(19) United States
(12) Patent Application Publication
(10) Pub. No.: US 2020/0398884 A1
(43) Pub. Date: Dec. 24, 2020

(54) SWITCH DEVICE

(71) Applicant: KABUSHIKI KAISHA TOKAI RIKA DENKI SEISAKUSHO, Aichi (JP)

(72) Inventors: Tatsushi KATSUYAMA, Aichi (JP); Takashi NAGAO, Aichi (JP); Tetsuya EGAWA, Aichi (JP); Takeyoshi MORI, Aichi (JP)

(73) Assignee: Kabushiki Kaisha Tokai Rika Denki Seisakusho, Aichi (JP)

(21) Appl. No.: 16/644,074

(22) PCT Filed: Aug. 28, 2018
(86) PCT No.: PCT/JP2018/031792

§ 371 Date: Mar. 3, 2020

(30) Foreign Application Priority Data
Sep. 19, 2017 (JP) 2017-179095

(51) Int. Cl. B62D 1/04; B62D 15/02; B60R 16/00; G08G 1/16; H01H 13/50; H01H 13/14

(52) U.S. Cl. CPC B62D 1/046; B62D 15/029; B60R 16/005; H01H 2215/052; H01H 13/50; H01H 13/14; G08G 1/167

(57) ABSTRACT

A switch device includes a switch part that is installed on a steering wheel of a vehicle and that includes an operation knob and an electromagnetic element for detecting an operation on the operation knob and causing a vibration of the operation knob, and a control unit that makes the operation knob vibrate. The control unit controls the electromagnetic element to vibrate under a predetermined condition so that vibration is transmitted to a hand of an occupant holding the steering wheel.

### CROSS-REFERENCES TO RELATED APPLICATIONS

The present application claims the priority of Japanese patent application No. 2017/179095 filed on Sep. 19, 2017, and the entire contents of Japanese patent application No. 2017/179095 are hereby incorporated by reference.

### TECHNICAL FIELD

The present invention relates to a switch device.

### BACKGROUND ART

An acoustic system is present which is mounted on a vehicle to inform the situation of the surroundings of the vehicle by a three-dimensional audio image. The acoustic system is provided with a speaker to emit a sound, and a control unit from which an output signal corresponding to the situation of the surroundings of the vehicle is output to the speaker (see, e.g., Patent Literature 1). The control unit has a means for deriving parameters associated with driving safety such as positions and relative speeds of plural running vehicles around own vehicle and inter-vehicle distances, a means for determining the imminent danger level for own vehicle by comparing the parameters to conditions which are preset for determining the imminent danger level, a signal conversion circuit means for converting a signal of the parameter into a virtual sound source generation signal according to the result of determining the imminent danger level, a means for converting the virtual sound source generation signal into a pulse-like amplified signal by using a signal amplifier circuit, and a signal processing circuit means which inputs the amplified signal to the speaker to produce pulse sound at a position of the virtual sound source.

### CITATION LIST

### Patent Literature

Patent Literature 1: JP 2002/133596 A

### SUMMARY OF INVENTION

### Technical Problem

The acoustic system disclosed in Patent Literature 1 causes a problem that it needs to be separately provided with the speaker to emit a sound as an announcement means to reliably inform a vehicle driver of the situation of the surroundings of the vehicle.

It is an object of the invention to provide a switch device which can be installed on a steering wheel to generate a vibration of the steering wheel as an announcement means.

### Solution to Problem

According to an embodiment of the invention, a switch device may be configured as defined by [1] to [10] below.
[1] A switch device, comprising: a switch part that is installed on a steering wheel of a vehicle and comprises an operation knob and an electromagnetic element for detecting an operation on the operation knob and causing a vibration of the operation knob; and a control unit that makes the operation knob vibrate, wherein the control unit controls the electromagnetic element to vibrate under a predetermined condition so that vibration is transmitted to the steering wheel and to a hand of an occupant holding the steering wheel.
[2] The switch device according to [1], wherein the operation knob comprises a plate-shaped panel and is arranged to be flush with a surface of the steering wheel.
[3] The switch device according to [1] or [2], wherein the operation knob is connected to the electromagnetic element via a transmission member.
[4] The switch device according to [3], wherein the transmission member comprises a columnar body comprising an elastic body.
[5] The switch device according to any one of [1] to [4], wherein the control unit makes the electromagnetic element generate a reaction force corresponding to the operation.
[6] The switch device according to any one of [1] to [5], wherein the control unit makes the electromagnetic element vibrate under the predetermined condition by a control signal corresponding to the natural frequency of the steering wheel or a multiple of the natural frequency.
[7] The switch device according to any one of [1] to [6], wherein the control unit is connected to a lane departure prevention system, and when the lane departure prevention system judges that lane departure possibly occurs, the control unit provides vibration notification to the hands of the occupant based on determination that the predetermined condition is satisfied.
[8] The switch device according to any one of [1] to [6], wherein the control unit is connected to a collision avoidance system, and when the collision avoidance system predicts a collision, the control unit provides vibration notification to the hands of the occupant based on determination that the predetermined condition is satisfied.
[9] The switch device according to any one of [1] to [8], wherein the electromagnetic element comprises a piezoelectric element.
[10] The switch device according to any one of [1] to [9], wherein the number of the switch parts provided on the steering wheel is at least two.

### Advantageous Effects of Invention

According to an embodiment of the invention, it is possible to provide a switch device which can be installed on a steering wheel to generate a vibration of the steering wheel as an announcement means.

### BRIEF DESCRIPTION OF DRAWINGS

FIG. 1 is a front view showing a switch device in an embodiment in the case of being mounted on a steering wheel of a vehicle when viewing the steering wheel from a driver.

FIG. 2 is a cross sectional view showing the switch device taken along a line A-A in FIG. 1.

FIG. 3 is a block diagram illustrating a configuration of the switch device in the embodiment.

FIG. 4 shows a waveform example of a drive signal for driving an operation knob, wherein a drive signal Sh1 is to provide tactile sensation by causing vibration of the operation knob in response to a touch operation, and a drive signal Sv1 is to cause vibration of the steering wheel through the operation knob.

### DESCRIPTION OF EMBODIMENTS

### Embodiment of the Invention

A switch device 1 in an embodiment of the invention has switch parts 30, 40 that are installed on a steering wheel 8 of a vehicle 5 and are provided with operation knobs 31, 41 and piezo elements 32, 42 acting as electromagnetic elements that detect an operation on the operation knobs 31, 41 and also cause vibration of the operation knobs 31, 41, and a control unit 100 that makes the operation knobs 31, 41 vibrate. Under predetermined conditions, the control unit 100 controls the piezo elements 32, 42 to vibrate so that vibration is transmitted to the steering wheel 8 and the hands of a driver that is an occupant holding the steering wheel 8.

In the present embodiment, an example in which the occupant is a driver will be described.

### (Switch Parts 30 and 40)

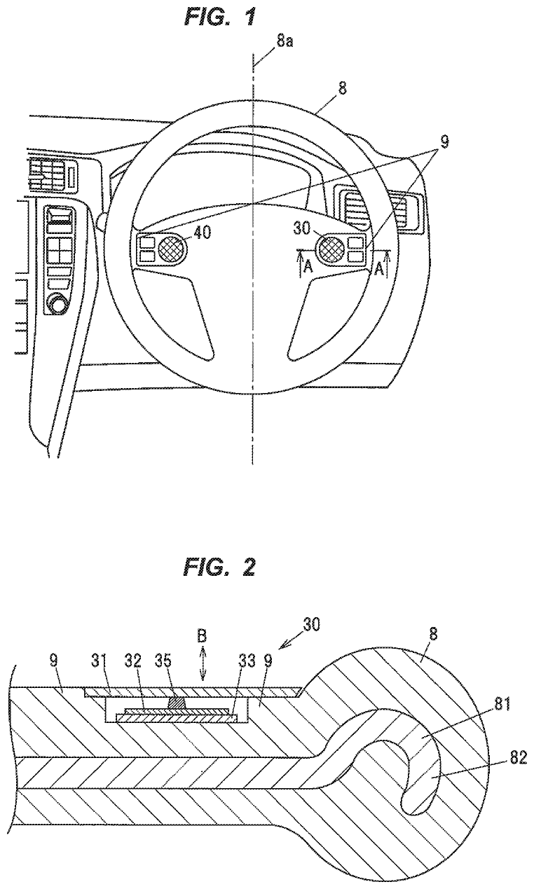

As shown in FIG. 1, the switch parts 30, 40 are attached to the steering wheel 8 of the vehicle 5. One or two or more switch parts are provided on the steering wheel 8. In the present embodiment, an example in which the two switch parts 30, 40 are symmetrically arranged across a center line 8a of the steering wheel 8 as shown in FIG. 1 will be described.

The switch parts 30, 40 are switches associated with vehicle operation and are steering switches which can be used for air-conditioning control, audio control, and car navigation operation, etc. The switch parts 30, 40 can be electrically connected to a vehicle main body via, e.g., a steering roll connector (not shown). The drive signal Sh1 to provide tactile sensation and the drive signal Sv1 to cause vibration of the steering wheel through the operation knob, etc., (described later) can be input from the vehicle main body via the steering roll connector.

As shown in FIG. 2, the switch part 30 is generally composed of the operation knob 31 which is a plate-shaped panel, and the piezo element 32 which is an electromagnetic element connected to the operation knob 31 via a transmission member 35. The transmission member 35 is a columnar body formed of a material capable of easily transmitting a force or vibration, e.g., a metal, a resin or an elastic body such as rubber. The piezo element 32 is mounted on a substrate 33 which is provided on a spoke 9. As shown in FIG. 2, the operation knob 31 is a plate-shaped panel and is arranged to be flush with the surface of the spoke 9, hence, a seamless switch with no level difference. The switch part 40 has the same configuration.

The piezo element 32 is, e.g., a unimorph piezoelectric element provided with a piezoelectric body having a disc shape and a metal shim having a disc shape with a larger radius than the piezoelectric body. An upper wiring is electrically connected to the piezoelectric body of the piezoelectric element and a lower wiring is electrically connected to the metal shim of the piezoelectric element.

As a modification, the piezoelectric element may be, e.g., a bimorph piezoelectric element in which two piezoelectric bodies are provided on both sides of the metal shim.

The material used to form the piezoelectric body is, e.g., lithium niobate, barium titanate, lead titanate, lead zirconate titanate (PZT), lead metaniobate or polyvinylidene fluoride (PVDF), etc. The piezoelectric body is, e.g., a stacked piezoelectric body formed by stacking films of these materials. The piezoelectric body is poled in a thickness direction and produces larger output when deformed in the thickness direction. The metal shim is formed of, e.g., conductive phosphor bronze or conductive stainless steel, etc.

When the operation knob 31 is pushed, the piezo element 32 generates voltage corresponding to the pushing force and produces a push operation signal S0. The piezo element 32 thereby acts as a switching element which detects an operation on the operation knob 31.

The piezo element 32 also deforms upon application of voltage and displaces the operation knob 31, which is connected thereto via the transmission member 35, in a vertical direction B shown in FIG. 2. The piezo element 32 as an electromagnetic element thereby can generate a reaction force corresponding to the push operation performed on the operation knob 31. That is, the piezo element 32 acts as an actuator which provides tactile sensation from the piezo element 32 side to the finger, etc., performing an operation on the operation knob 31.

Meanwhile, the steering wheel 8 is formed by covering a metal core 81 with a resin part 82, as shown in FIG. 2. The switch part 30 installed on the spoke 9 of the steering wheel 8 can provide vibration notification by transmitting the above-described vibration of the piezo element 32 through the metal core 81 and the resin part 82 to the hand or fingers holding the steering wheel 8.

Therefore, the switch part 30 can announce a warning under the predetermined conditions. For example, when a warning signal Sk (described later) is output, the metal core 81 is vibrated by vibration of the piezo element 32 and this allows vibration notification to be provided to the hand or fingers of the driver holding the resin part 82.

The steering wheel 8 has the natural frequency corresponding to plural vibration modes because of its structure. The switch part 30 is configured that the piezo element 32 can be displaced in the vertical direction B shown in FIG. 2 by applying voltage by a control signal corresponding to the natural frequency. Alternatively, the piezo element 32 can be displaced in the vertical direction B shown in FIG. 2 by applying voltage by a control signal corresponding to a multiple of the natural frequency. This configuration allows the switch part 30 to cause vibration of the steering wheel 8, thereby efficiently providing vibration notification to the hand or fingers of the driver.

By having such a configuration, the switch part 30 serves to provide tactile sensation in response to the push operation on the operation knob 31 and also serves as a warning announcement means which provides vibration notification to the hand or fingers of the driver under the predetermined conditions by causing vibration of the steering wheel 8.

The electromagnetic element is not limited to the piezo element 32 described above. It is possible to use, e.g., a voice coil motor which is composed of a magnetic circuit and a coil and is configured to detect an operation force on the coil based on a current produced in the coil by the movement thereof and to generate vibration by movement of the coil caused by a change in the magnetic field on the magnetic circuit side.

### (Configuration of the Control Unit 100)

The control unit 100 is provided with, e.g., a microcomputer composed of a CPU (Central Processing Unit) performing predetermined calculation and processing, etc., according to a stored program, a RAM (Random Access Memory) and a ROM (Read Only Memory) as semiconductor memories, etc. The ROM stores, e.g., a program for operation of the control unit 100 and various parameters, etc.

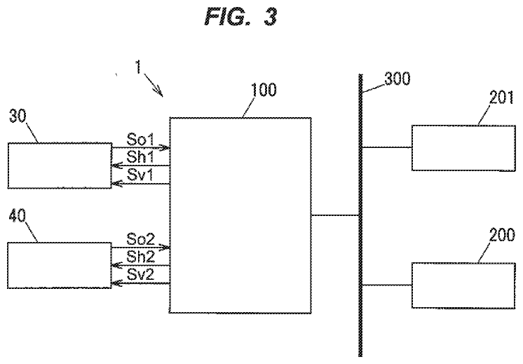

As shown in FIG. 3, the switch parts 30, 40 are connected to the control unit 100. Push operation signals S_{O1} and S_{O2} are input from the switch parts 30, 40. Then, in response to the push operation signals S_{O1} and S_{O2}, tactile sensation presentation signals Sh1, Sh2 to provide tactile sensation are output to the piezo elements 32, 42 of the switch parts 30, 40. In addition, drive signals Sv1, Sv2 to output warning tones or warning sound, etc., are also output to the piezo elements 32, 42 of the switch parts 30, 40.

A device to assist vehicle driving safety is also connected to the control unit 100, via, e.g., an in-vehicle LAN 300. For example, a lane departure prevention system 200 is connected to the control unit 100. Thus, when the warning signal Sk (described later) is output, the control unit 100 can perform control to transmit vibration to the steering wheel 8 and to the hands of an occupant 20 holding the steering wheel 8, based on determination that the predetermined conditions are satisfied.

The lane departure prevention system 200 is also called lane keeping assist, and issues a warning to a driver by an announcement means such as a warning buzzer to prevent an accident due to lane departure when a vehicle is about to depart from a currently running lane. Furthermore, when a radar cruise control is activated, it is possible to help drive along the lane by supporting driver's steering manipulation. The method used is such that, e.g., a camera perceives the road shape (while line, yellow line) and the warning signal Sk is output when the lane departure prevention system 200 judges that lane departure possibly occurs. The driver is warned by the warning buzzer or display, etc., so that lane departure is prevented.

In another method, the control unit 100 is connected to an in-vehicle driving safety assistance system such as a collision avoidance system 201 which detects vehicles ahead by a radar, a laser and a monocular camera and issues a warning when a collision is predicted, and the warning signal Sk is output from both under the predetermined conditions.

### (Tactile Sensation Presentation Control by the Control Unit 100)

Based on the push operation signals SO1, SO2, the control unit 100 makes the piezo elements 32, 42 generate a reaction force corresponding to the push operation performed on the operation knob 31 and provides tactile sensation by vibration, etc., to an operator operating the operation knobs 31, 41. When a push operation is performed, the control unit 100 outputs the tactile sensation presentation signals Sh1, Sh2 to the piezo elements 32, 42 to, e.g., thrust the operation knobs 31, 41 upward once or several times with a predetermined force, thereby providing tactile sensation. Alternatively, tactile sensation can be provided by vibrating at a predetermined cycle.

### (Steering Wheel Vibration Control by the Control Unit 100)

In addition to tactile sensation presentation control, the control unit 100 performs control to transmit vibration to the steering wheel 8 and to the hands of the occupant 20 holding the steering wheel 8 under the predetermined conditions.

### (Operation Example of the Switch Parts 30 and 40)

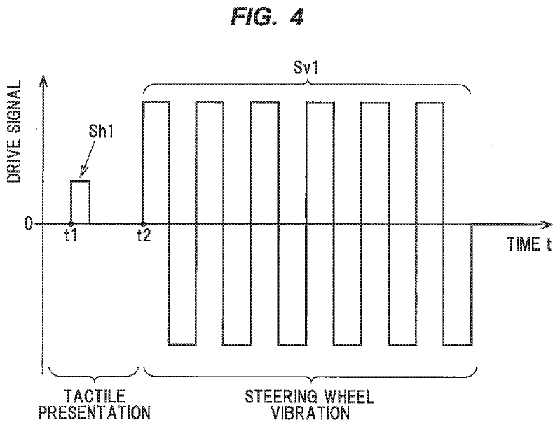

The operation of the switch parts 30, 40 will be described using a waveform example of the drive signal shown in FIG. 4 which is a signal for driving the operation knob of the right switch part 30. The control unit 100 outputs, e.g., the drive signal Sh1 for tactile sensation presentation to the piezo element 32 at time t1 in response to the push operation on the operation knob and thereby makes the operation knob 31 vibrate. Tactile sensation is presented by, e.g., motion of thrusting the operation knob 31 upward by a single pulse, as shown in FIG. 4.

Then, under the predetermined conditions, the control unit 100 outputs, e.g., the drive signal Sv1 as a pulse signal to the piezo element 32 at time t2 and thereby makes the operation knob 31 vibrate. The drive signal Sv1 is to vibrate the steering wheel 8 and is preferably larger than the drive signal Sh1 for tactile sensation presentation.

The switch device 1 provides vibration notification by transmitting the vibration of the piezo element 32 through the metal core 81 and the resin part 82 to the hand or fingers holding the steering wheel 8. That is, when the warning signal Sk output from in-vehicle devices such as the lane departure prevention system 200 or the collision avoidance system 201 satisfies the predetermined conditions, the steering wheel 8 is vibrated by vibration of the operation knob 31 of the switch part 30, thereby providing vibration notification to the hand or fingers of the driver.

### Effects of the Embodiment

The following effects are obtained in embodiment of the invention.
(1) The switch device in the embodiment of the invention has the switch parts 30, 40 that are installed on the steering wheel 8 of the vehicle 5 and are provided with the operation knobs 31, 41 and the piezo elements 32, 42 acting as electromagnetic elements that detect an operation on the operation knobs 31, 41 and also cause vibration of the operation knobs 31, 41, and the control unit 100 that makes the operation knobs 31, 41 vibrate. Under predetermined conditions, the control unit 100 controls the piezo elements 32, 42 to vibrate so that vibration is transmitted to the steering wheel 8 and to the hands of a driver that is an occupant holding the steering wheel 8. In this configuration, the switch part serves to provide tactile sensation in response to the push operation on the operation knob and also serves as a warning announcement means which provides vibration notification to the hand or fingers of the driver under the predetermined conditions by causing vibration of the steering wheel 8.
(2) Since it is possible to mount the switch part on the steering wheel, etc., of the vehicle main body, it is not necessary to separately mount an actuator such as a motor unit for vibrating the steering wheel and this allows the periphery of the steering switches to be small in size.
(3) Since the switch part can be mounted on the steering wheel, etc., of the vehicle main body and can cause vibration of the steering wheel 8, it is not necessary to separately mount an actuator and it is also possible to have a warning announcement means for providing vibration notification to the hand or fingers of the driver without increasing the cost.

Although some embodiments of the invention have been described above, the embodiments are merely exemplary and the invention according to claims is not to be limited thereto. These new embodiments may be implemented in various other forms, and various omissions, substitutions and changes, etc., can be made without departing from the gist of the invention. In addition, all combinations of the features described in these embodiments are not necessary to solve the problem of the invention. Further, these embodiments are included within the scope and gist of the invention and also within the invention described in the claims and the equivalency thereof.

### REFERENCE SIGNS LIST

1 SWITCH DEVICE
5 VEHICLE
8 STEERING WHEEL
8a CENTER LINE
9 SPOKE
30 SWITCH PART
31 OPERATION KNOB
32 PIEZO ELEMENT
33 SUBSTRATE
35 TRANSMISSION MEMBER
40 SWITCH PART
100 CONTROL UNIT
200 LANE DEPARTURE PREVENTION SYSTEM
201 COLLISION AVOIDANCE SYSTEM

1. A switch device, comprising:
a switch part that is installed on a steering wheel of a vehicle and that comprises an operation knob and an electromagnetic element for detecting an operation on the operation knob and causing a vibration of the operation knob; and
a control unit that makes the operation knob vibrate,
wherein the control unit controls the electromagnetic element to vibrate under a predetermined condition so that vibration is transmitted to a hand of an occupant holding the steering wheel.

2. The switch device according to claim 1, wherein the operation knob comprises a plate-shaped panel and is arranged to be flush with a surface of the steering wheel.

3. The switch device according to claim 1, wherein the operation knob is connected to the electromagnetic element via a transmission member.

4. The switch device according to claim 3, wherein the transmission member comprises a columnar body comprising an elastic body.

5. The switch device according to claim 1, wherein the control unit makes the electromagnetic element generate a reaction force corresponding to the operation.

6. The switch device according to claim 1, wherein the control unit makes the electromagnetic element vibrate under the predetermined condition by a control signal corresponding to the natural frequency of the steering wheel or a multiple of the natural frequency.

7. The switch device according to claim 1, wherein the control unit is connected to a lane departure prevention system, and when the lane departure prevention system judges that lane departure possibly occurs, the control unit provides vibration notification to the hands of the occupant based on determination that the predetermined condition is satisfied.

8. The switch device according to claim 1, wherein the control unit is connected to a collision avoidance system, and when the collision avoidance system predicts a collision, the control unit provides vibration notification to the hands of the occupant based on determination that the predetermined condition is satisfied.

9. The switch device according to claim 1, wherein the electromagnetic element comprises a piezoelectric element.

10. The switch device according to claim 1, wherein the number of the switch parts provided on the steering wheel is at least two.
